(19) United States
(12) Patent Application Publication
(10) Pub. No.: US 2025/0159913 A1
(43) Pub. Date: May 15, 2025

(54) BIPOLAR TRANSISTOR STRUCTURE WITH BOUNDING STRUCTURE AT HORIZONTAL END AND METHODS TO FORM SAME

(71) Applicant: GlobalFoundries U.S. Inc., Malta, NY (US)

(72) Inventors: Judson Robert Holt, Ballston Lake, NY (US); Peter Baars, Dresden (DE); Alexander M. Derrickson, Saratoga Springs, NY (US)

(21) Appl. No.: 18/506,033

(22) Filed: Nov. 9, 2023

(51) Int. Cl. H01L 29/737; H01L 21/8249; H01L 27/06; H01L 29/10; H01L 29/66

(52) U.S. Cl. CPC H10D 10/80; H10D 10/021; H10D 62/184; H10D 84/0109; H10D 84/038; H10D 84/401

(57) ABSTRACT

Embodiments of the disclosure provide a structure including a first emitter/collector (E/C) layer over a substrate. A base structure is over the substrate and adjacent a first horizontal end of the first E/C layer. A bounding structure is over the substrate and adjacent a second horizontal end of the first E/C layer. The bounding structure, in some implementations, may include a gate conductor or a base material. A spacer is between the first E/C layer and the bounding structure.

### STATEMENT REGARDING FEDERAL RIGHTS

This invention was made with government support under DARPA T-MUSIC program Agreement No. HR0011-20-3-0002 awarded by the United States Department of Defense. The government has certain rights in the invention.

### BACKGROUND

The present disclosure provides a lateral bipolar junction transistor (BJT) and methods to form the same.

Conventional integrated circuits may employ heterojunction bipolar transistors (HBTs). Historically, HBTs were vertically oriented. Lateral bipolar transistors are currently under development, at least in part, to allow for easy integration into complementary metal oxide semiconductor (CMOS) process flows for semiconductor-on-insulator structures (e.g., silicon-on-insulator (SOI) structures).

### SUMMARY

The illustrative aspects of the present disclosure are designed to solve the problems herein described and/or other problems not discussed.

Embodiments of the disclosure provide structure including: a first emitter/collector (E/C) layer over a substrate; a base structure over the substrate and adjacent a first horizontal end of the first E/C layer; a bounding structure over the substrate and adjacent a second horizontal end of the first E/C layer, wherein the bounding structure includes a base material; and a spacer between the first E/C layer and the bounding structure.

Other embodiments of the disclosure provide a structure including: a first emitter/collector (E/C) layer over a substrate; a base structure over the substrate and adjacent a first horizontal end of the first E/C layer, wherein the base structure includes a base material; a bounding structure over the substrate and adjacent the first horizontal end of the first E/C layer, wherein the bounding structure includes a gate conductor having a different composition from the base material; and a spacer between the first E/C layer and the bounding structure.

Additional embodiments of the disclosure provide a method including: providing a substrate; and forming a bipolar junction transistor including at least: a first emitter/collector (E/C) layer on the substrate; a base structure on the semiconductor layer and adjacent a first horizontal end of the first E/C layer; a bounding structure over the semiconductor layer and adjacent a second horizontal end of the first E/C layer, wherein the bounding structure includes a base material; and a spacer between the first E/C layer and the bounding structure.

### BRIEF DESCRIPTION OF THE DRAWINGS

These and other features of this disclosure will be more readily understood from the following detailed description of the various aspects of the disclosure taken in conjunction with the accompanying drawings that depict various embodiments of the disclosure, in which:

FIG. 1 shows a cross-sectional view of a bipolar transistor structure with a bounding structure according to embodiments of the disclosure.

FIG. 2 shows a cross-sectional view of a bipolar transistor structure with a bounding structure according to embodiments of the disclosure.

FIG. 3 shows a cross-sectional view of a bipolar transistor and adjacent metal oxide semiconductor field effect transistor (MOSFET) structure separated by a bounding structure according to embodiments of the disclosure.

FIG. 4 shows a cross-sectional view of two bipolar transistors with opposite polarity separated by a bounding structure according to embodiments of the disclosure.

FIG. 5 shows a plan view of bipolar transistor structures with opposite polarity connected through bounding structures according to embodiments of the disclosure.

FIGS. 6-12 show cross-sectional views illustrating methods to form a structure according to embodiments of the disclosure.

It is noted that the drawings of the disclosure are not necessarily to scale. The drawings are intended to depict only typical aspects of the disclosure, and therefore should not be considered as limiting the scope of the disclosure. In the drawings, like numbering represents like elements between the drawings.

### DETAILED DESCRIPTION

In the following description, reference is made to the accompanying drawings that form a part thereof, and in which is shown by way of illustration specific illustrative embodiments in which the present teachings may be practiced. These embodiments are described in sufficient detail to enable those skilled in the art to practice the present teachings, and it is to be understood that other embodiments may be used and that changes may be made without departing from the scope of the present teachings. The following description is, therefore, merely illustrative.

It will be understood that when an element such as a layer, region, or substrate is referred to as being “on” or “over” another element, it may be directly on the other element or intervening elements may also be present. In contrast, when an element is referred to as being “directly on” or “directly over” another element, there may be no intervening elements present. It will also be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present.

Reference in the specification to “one embodiment” or “an embodiment” of the present disclosure, as well as other variations thereof, means that a particular feature, structure, characteristic, and so forth described in connection with the embodiment is included in at least one embodiment of the present disclosure. Thus, the phrases “in one embodiment” or “in an embodiment,” as well as any other variations appearing in various places throughout the specification are not necessarily all referring to the same embodiment. It is to be appreciated that the use of any of the following “/,” “and/or,” and “at least one of,” for example, in the cases of “A/B,” “A and/or B” and “at least one of A and B,” is intended to encompass the selection of the first listed option (a) only, or the selection of the second listed option (B) only, or the selection of both options (A and B). As a further example, in the cases of “A, B, and/or C” and “at least one of A, B, and C,” such phrasing is intended to encompass the first listed option (A) only, or the selection of the second listed option (B) only, or the selection of the third listed option (C) only, or the selection of the first and the second listed options (A and B), or the selection of the first and third listed options (A and C) only, or the selection of the second and third listed options (B and C) only, or the selection of all three options (A and B and C). This may be extended, as readily apparent by one of ordinary skill in the art, for as many items listed.

Embodiments of the disclosure provide a bipolar transistor structure with a bounding base at its horizontal end, and methods to form the same. A structure according to the disclosure may include a first emitter/collector (E/C) layer on an insulator layer. A base structure is over the insulator layer and adjacent a first horizontal end of the first E/C layer. A bounding structure is over the insulator layer and adjacent a second horizontal end of the first E/C layer. The bounding structure, in some implementations, may include a gate conductor or a base material. A spacer is between the first E/C layer and the bounding structure. As compared with conventional bipolar transistors, the presence of a bounding structure may reduce base and/or gate resistances in a device during operation and permits greater customizing of the junction profile within the bipolar transistor (e.g., by electrical biasing of the bounding structure). In the case where the bipolar transistor includes a gate conductor, the bounding structure may define a “tie down gate” for selectively coupling or decoupling two adjacent bipolar transistors on one substrate.

Bipolar junction transistor (BJT) structures, such as those in embodiments of the disclosure, operate using multiple “P-N junctions.” The term “P-N” refers to two adjacent materials having different types of conductivity (i.e., P-type and N-type), which may be induced through dopants within the adjacent material(s). A P-N junction, when formed in a device, may operate as a diode. A diode is a two-terminal element, which behaves differently from conductive or insulative materials between two points of electrical contact. Specifically, a diode provides high conductivity from one contact to the other in one voltage bias direction (i.e., the “forward” direction), but provides little to no conductivity in the opposite direction (i.e., the “reverse” direction). In the case of the P-N junction, the orientation of a diode's forward and reverse directions may depend on the type and magnitude of bias applied to the material composition of one or both terminals, affecting the size of the potential barrier. In the case of a junction between two semiconductor materials, the potential barrier will be formed along the interface between the two semiconductor materials.

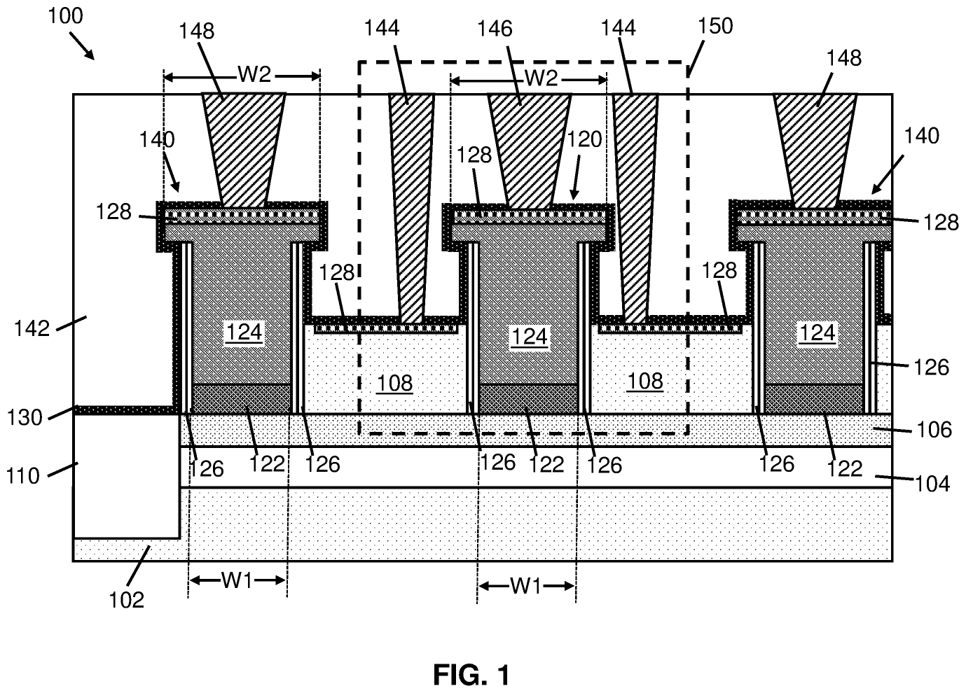

Referring to FIG. 1, a structure 100 according to embodiments of the disclosure is shown. Structure 100 may be on a substrate 102 including, e.g., one or more semiconductor materials. Substrate 102 may include but is not limited to silicon, germanium, silicon germanium (SiGe), silicon carbide (SiC), or any other common IC semiconductor substrates. In the case of SiGe, the germanium concentration in substrate 102 may differ from other SiGe-based structures described herein. A portion or entirety of substrate 102 may be strained, and/or may be doped to any desired polarity or concentration. In addition, some portions of substrate 102 may be doped to provide deep wells, e.g., for other device structures on substrate 102 not explicitly shown or discussed herein.

Structure 100 may include embedded elements for electrically separating active materials formed over substrate 102 from other regions and/or materials. An insulator layer 104 can be above and immediately adjacent to substrate 102. Insulator layer 104 can be, for example, an oxide layer (also referred to herein as a buried oxide (BOX) layer), such as a silicon dioxide layer, or a layer of any other suitable insulator material. A semiconductor layer 106 can be above and immediately adjacent to insulator layer 104. Semiconductor layer 106 can specifically be a monocrystalline semiconductor layer. For example, the semiconductor layer 106 can be a monocrystalline silicon layer (also referred to herein as a silicon-on-insulator (SOI) layer) or a monocrystalline layer of any other suitable semiconductor material (e.g., silicon germanium).

Structure 100 also may include one or more trench isolation layers (TI(s)) 110. TI layer(s) 110 may be made by forming and filling trenches (not labeled) with an insulating material such as oxide. TI layer(s) 110 horizontally isolate insulator layer 104, semiconductor layer 106, and other components such as E/C layer(s) 108, and layers thereon from any adjacent regions of material. Various portions of structure 100, including the active semiconductor materials thereof and/or other devices where applicable, may be formed on or above portions of insulator layer 104 that are isolated by TI layer(s) 110. One TI layer 110 is shown in FIG. 1 as an example, but multiple TI layer(s) 110 may be provided as discussed elsewhere herein to isolate structure 100 from different types of structures and/or components. Semiconductor layer(s) 106 between TI layers 110 can define an active device region for a lateral bipolar junction transistor 150 in the semiconductor layer 106. TI layer(s) 110 may be formed before active materials are formed over substrate 102, but this is not necessarily true in all implementations.

The structure 100 can include a lateral BJT 150, which is optionally a lateral HBT, as discussed below. The BJT 150 can be formed on, or otherwise include, active semiconductor material(s) bounded within TI layer(s) 110. BJT 150 in particular can include a set of emitter/collector (E/C) layers 108 and various base materials positioned laterally between (and isolated from) E/C layers 108. The E/C layers 108 may be formed by deposition and/or epitaxial growth of silicon and/or other semiconductor materials on semiconductor layer 106 and may have a predetermined conductivity (i.e., doping) type, e.g., by being doped in-situ or during formation of semiconductor material over insulator layer 104 and/or semiconductor layer 106. The E/C layers 108 can be monocrystalline in structure. The conductivity type and/or level of E/C layers 108 may be different from the conductivity type and/or level of the portion of the semiconductor layer 106 thereunder, and E/C layers 108 optionally may have a different composition (e.g., silicon germanium (SiGe)) relative to semiconductor layer 106. According to an example, semiconductor layer 106 may be undoped or only lightly doped with a first conductivity type, while E/C layers 108 may be more highly doped with an opposite conductivity type to provide active semiconductor material for use in the emitter and collector terminals of a lateral BJT structure. It is understood that localized implants and/or dopant diffusion from subsequent anneal steps may result in dopants of the same type as E/C layers 108 also being in portions of semiconductor layer 106 below and adjacent to E/C layers 108.

Each TI layer 110 may be formed of any currently-known or later developed substance for providing electrical insulation, and as examples may include: silicon nitride (Si₃N₄), silicon oxide (SiO₂), fluorinated SiO₂ (FSG), hydrogenated silicon oxycarbide (SiCOH), porous SiCOH, boro-phospho-silicate glass (BPSG), silsesquioxanes, carbon (C) doped oxides (i.e., organosilicates) that include atoms of silicon (Si), carbon (C), oxygen (O), and/or hydrogen (H), thermosetting polyarylene ethers, a spin-on silicon-carbon containing polymer material, near frictionless carbon (NFC), or layers thereof. In some cases, E/C layers 108 may extend to a height above the horizontally adjacent TI layer(s) 110, e.g., due to being formed by epitaxial growth of semiconductor material(s). In other cases, TI layer(s) 110 and EC layers 108 may be planarized (e.g., by chemical mechanical planarization or other technique(s)) such that the upper surface(s) thereof is/are substantially coplanar with each other.

Insulator layer 104 may extend horizontally throughout structure 100, and/or may be formed selectively under locations where active materials are formed, examples of which are discussed elsewhere herein. In further implementations, insulator layer 104 may include oxygen doping to form a dielectric insulator or a buried oxide (“BOX”) layer over substrate 102 to electrically isolate semiconductor layer 106 and/or E/C layer 108 from substrate 102. Insulator layer 104 thus may include other elements or molecules such as Ge, N, or Si. However embodied, insulator layer 104 may be sized as narrow as possible to provide better interaction with overlying semiconductor materials (e.g., semiconductor layer 106, E/C layers 108, and components formed thereon or therefrom). In various embodiments, insulator layer 104 may have a thickness of approximately two nanometers (nm), but may have a variety of thicknesses such as approximately twenty nm, approximately five-hundred nm, etc. Some portions (not shown) of substrate 102 may not have insulator layer 104 thereover, and/or multiple layers of insulator layer 104 may be formed on substrate 102 to varying thicknesses. Additionally, various conductive particles (“dopants”) may be introduced into substrate 102 as discussed herein via a process known as “pre-doping” of substrate 102. It is understood that substrate 102 can be separately connected and used as a “back bias” to modify the operation of some or all of the devices located above the insulator layer 104, even though such couplings are not explicitly shown in the accompanying FIGS. for clarity of illustration.

Structure 100 may include a base structure 120 on semiconductor layer 106, e.g., to provide physical structure for controlling current flow between the emitter and collector of a bipolar transistor within structure 100. Base structure 120 may include an intrinsic base layer 122 on a portion of semiconductor layer 106 and a base material 124 (e.g., crystalline Si or SiGe) on intrinsic base layer 122. Intrinsic base layer 122 may be monocrystalline Si, monocrystalline SiGe, and/or similar semiconductor materials with relatively low amounts of doping. Intrinsic base layer 122 may be located above the semiconductor layer 106 (as shown by example in the FIGS.) or it may be extend downward into layer 106. The doping type of intrinsic base layer 122 may be adjustable to provide NPN or PNP-conductivity types in a bipolar transistor. Base material 124, in some cases, may be initially formed as a placeholder material (e.g., polycrystalline silicon) that is later replaced with active semiconductor material within base structure 120. Base material 124 may include, or may be replaced with, an extrinsic base layer in by selective epitaxial growth of polycrystalline semiconductor in an opening above intrinsic base layer 122. Base structure 120 also may include a set of spacers 126 on outer surfaces of intrinsic base layer 122 and/or base material 124. Spacers 126 can be provided as one or more bodies of insulating material formed on the upper surface of a material, e.g., by deposition, thermal growth, etc., to electrically and physically insulate materials subsequently formed on the coated material(s) from other components. According to an example, spacer(s) 126 may have one or more nitride insulator materials (e.g., SiN) or other types of insulator materials (e.g., SiO₂) formed to a desired thickness. In this case, spacer(s) 126 alternatively may be formed, e.g., by nitriding exposed outer surfaces of base material 124 to convert its material composition into a nitride insulator (e.g., converting from poly-Si to silicon dioxide (SiN) or other semiconductor oxides).

In addition to providing electrical insulation, spacer(s) 126 may affect the shape of base material 124 over semiconductor layer 106. For instance, base material 124 may be substantially T-shaped by having a lower portion that is horizontally between (e.g., physically constrained by) spacer(s) 126, and an upper portion that extends horizontally over (and thus overhangs) spacer(s) 126. In further implementations, base material 124 may have any of a variety of structural configurations that are not T-shaped. Lower portions of base material 124 may have a first width W1 between spacers 126 that is less than a second width W2 of base material 124. Second width W2, in particular, may be larger than the horizontal distance between outer sidewalls of spacers 126. The position and size of spacer(s) 126 may be controlled during processing to further affect the size and shape of base material 124. It is understood that base material may be formed to have other geometries (e.g., shapes other than a “T”) by omitting or changing the shape or position of spacer(s) 126.

Structure 100 may include silicide layers 128 on E/C layers 108, base material 124, and other active semiconductor regions e.g., by providing a conductive metal such as cobalt (Co), titanium (Ti), nickel (Ni), platinum (Pt), or similar material on the upper surface(s) of a targeted material. The conductive material may be annealed while in contact with the underlying semiconductor to produce silicide layers 128 for electrically coupling semiconductor materials to contacts formed thereon. Excess conductive material can then be removed using any now known or later developed solution, e.g., etching.

Structure 100 also may include an insulative coating 130 over overlying semiconductor layer 106, upper surfaces and sidewalls of base structure 120 (including, e.g., base material 124, spacer(s) 126 and silicide layer(s) 128 thereof), adjacent TI layer(s) 110 and other structures, etc. Insulative coating 130 may be formed by deposition or other techniques of forming an insulative material on a structure. Additional metallization layers (not shown) may be formed on insulative coating 130 in subsequent processing during middle-of-line and/or back-end-of-line processing. Insulative coating 130 may include any currently known or later developed insulative layer, e.g., those included within insulator layer 104 and/or TI layer(s) 110. Despite insulative coating 130 possibly having a similar or identical composition to such materials, it is formed separately from other insulative material and physical boundaries and/or interfaces between insulative coating 130 and other such materials may be present in the structure.

A bounding structure 140 may be over insulator layer 104 (e.g., it may be on semiconductor layer 106) in a position laterally adjacent one E/C layer 108, e.g., such that E/C layer 108 is horizontally between gate structure 120 and bounding structure 140. Bounding structure 140 may take a variety of forms, and generally includes an additional layer of semiconductor material that is over insulator 104, and optionally, capable of electrically biasing adjacent and/or underlying regions of semiconductor material. In the example shown in FIG. 1, bounding structure 140 may be similar or identical to base structure 120 but is not horizontally between two E/C layers 108 (e.g., it is adjacent only one E/C layer 108 and/or does not function as a bipolar transistor base terminal). In addition, bounding structure 140 may be in a position where no other base or gate structures are horizontally interposed between bounding structure 140 and an adjacent TI layer 110. Bounding structure 140 may include intrinsic base layer 122 on semiconductor layer 106, base material 124 on intrinsic base layer 122, spacer(s) 126 on sidewalls of base material 124, silicide layer(s) on base material 124, and/or insulative coating 130 on upper surfaces and sidewalls of bounding structure 140. In some cases, either of intrinsic base layer 122 or base material 124 may be omitted such that only a uniform region of semiconductor base material is present. Bounding structure 140 also may be T-shaped and thus may have a lower portion with first width W1 between spacers 126 and an upper portion with second width W2 that is larger than the span between spacers 126. Although two bounding structures 140 are shown in FIG. 1, each on an opposing horizontal end of BJT structure 150, this is not necessarily required in all implementations.

Structure 100 may include an inter-level dielectric (ILD) layer 142 on insulative coating(s) 130 and above semiconductor layer 106, E/C layers 108, base structure(s) 120 and bounding structure(s) 140. ILD layer 142 may include the same insulating material as insulator layer 104 or may include a different electrically insulative material for vertically separating active materials from overlying materials, e.g., various horizontally extending wires or vias. ILD layer 142 and insulator layer 104 nonetheless constitute different components, e.g., due to insulator layer 104 initially being below E/C layer(s) 108. ILD layer 142 may be formed by deposition and/or other techniques to provide electrically insulating materials, and can then be planarized (e.g., using CMP), such that its upper remains above E/C layer(s) 108, base structure(s) 120, and bounding structure(s) 140 such that it covers these materials.

Structure 100 may include a set of E/C contacts 144 on E/C layers 108 and within ILD layer 142. Similarly, a base contact 146 contacting base material 124 of base structure 120 may be located within ILD layer 142. Optionally, a set of bounding contacts 148 may be on upper surfaces of bounding structure(s) 140 to allow electrical biasing of bounding structure(s) 140 (e.g., using contacts to base material 124). One or more of contacts 144, 146, 148 to overlying circuit elements may be formed within predetermined portions of ILD layer 142 by a controlled amount of vertical etching to form openings to one or more contact sites, and then filling the openings with a conductor. Each contact 144, 146, 148 may include any currently known or later developed conductive material configured for use in an electrical contact, e.g., tungsten (W), copper (Cu), aluminum (Al), etc. Contacts 144, 146, 148 may additionally include refractory metal liners (not shown) positioned alongside ILD layer 142 to prevent electromigration degradation, shorting to other components, etc. In structure 100, a BJT structure 150 includes E/C layer(s) 108 coupled to E/C contacts 144, base structure 120, base contact(s) 146 coupled to base structure 120, and portions of semiconductor layer 106 coupling E/C layer(s) 108 to base structure 120. Bounding structure(s) 140 is/are not considered part of BJT structure 150, as they do not provide a current for transmission and/or control electrical coupling of E/C layers 108 through base structure 120. However, bounding structure(s) 140 optionally may allow electrical biasing of BJT structure 150 and/or may allow one BJT structure 150 to be connected to another as discussed in further detail herein.

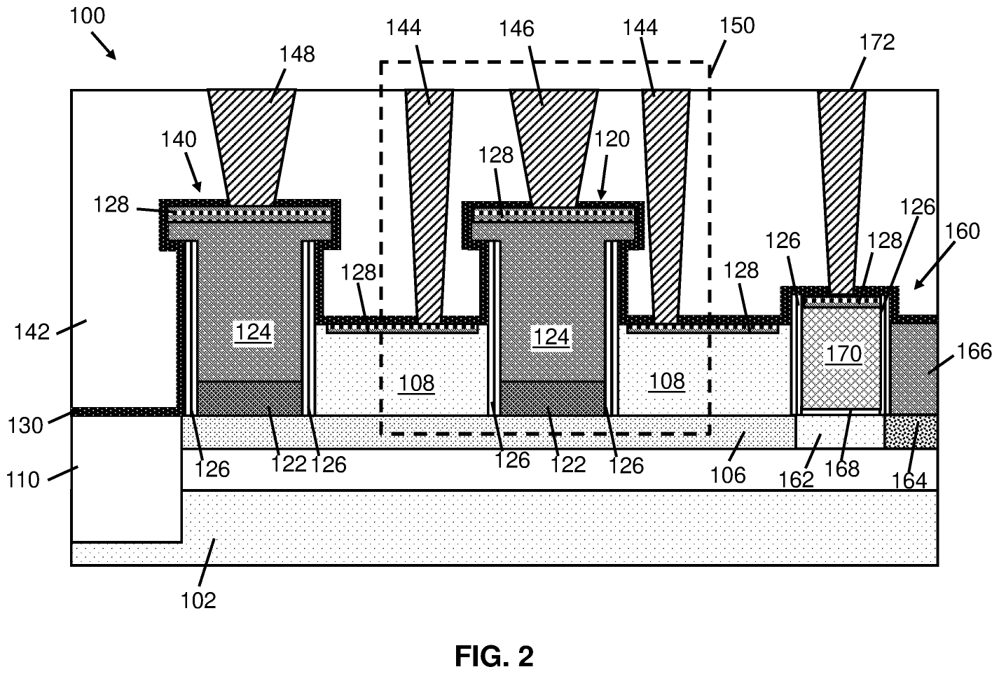

FIG. 2 depicts a further implementation of structure 100, in which a bounding structure 160 includes features different from those of bounding structure 140 discussed elsewhere herein. In contrast to bounding structure 140, which may be similar or identical to base structure 120 of BJT structure 150, bounding structure 160 more closely resembles the gate of a field effect transistor (FET) and may take the form of a “tie down gate.” A “tie down gate” refers to a gate structure for electrically coupling or decoupling two regions of active semiconductor material, in which each region may have its own distinct transistor structure(s) therein. Although bounding structure 140 and 160 are shown on opposite sides of BJT structure 150 in FIG. 2 for the sake of example, it is understood that only one type of bounding structure (i.e., bounding structure 140 or bounding structure 160) may be provided in structure 100 where desired and/or applicable. Semiconductor layer 106 may include a channel region 162, which may be an undoped or more lightly doped region of semiconductor material as compared to semiconductor layer 106. An additional SOI layer 164 may be adjacent channel region 162, and optionally may have a different conductivity type from semiconductor layer 106. Additional SOI layer 164, for instance, may have the same doping type as E/C layer 108 due to out-diffusion of dopants from E/C layer 108. Semiconductor layer 106, by contrast, may be undoped or only lightly doped. Where additional SOI layer 164 defines part of another bipolar transistor structure (not shown in FIG. 2), an additional E/C layer 166 may be on additional SOI layer 164. Additional E/C layer 166 similarly may have an opposite conductivity type from E/C layer 108. In this configuration, bounding structure 160 may be horizontally interposed between E/C layers 108, 166.

Bounding structure 160 may include the components of a FET gate structure, e.g., to provide a tie-down gate between BJT structure 150 and other active devices on substrate 102. Bounding structure may include a gate dielectric layer 168 on channel region 162. Gate dielectric layer 168 may include any thin layer of dielectric material capable of preventing electrical coupling between channel region 162 and electrically active material(s) over gate dielectric layer 168 while allowing electric fields within bounding structure 160 to influence the electrical conductivity within channel region 162. Gate dielectric layer 168 may include, e.g., a “high-k” dielectric material (i.e., any material having a dielectric constant of at least 3.9) or other currently known or later developed gate dielectric materials, and as examples may include hafnium silicate (HfSiO), hafnium oxide (HfO₂), zirconium silicate (ZrSiOₓ), zirconium oxide (ZrO₂), silicon oxide (SiO₂), silicon nitride (Si₃N₄), silicon oxynitride (SiON), or any combination of these materials.

Bounding structure 160 also may include a gate conductor material 170 including a conductive metal (e.g., copper, aluminum, and/or other metal wiring materials), and/or an active semiconductor material (e.g., doped polycrystalline Si and/or SiGe) over gate dielectric layer 168. In the case where gate material 170 includes active semiconductor material, gate material 170 may include silicide layer 128 thereon for improving the electrical interface between bounding structure 160 and metal wires and/or vias coupled thereto. A gate contact 172 within ILD layer 142 may vertically couple gate material 170 of bounding structure 160 to metal wires, vias, and/or other components through wiring layers (not shown) above ILD layer 142. Another set of spacers 126 and portions of insulative coating 130 also may cover upper surfaces and sidewalls of bounding structure 160, e.g., in a manner similar to that of bounding structure 140. Bounding structure 160 may be located adjacent E/C layer 108 but may not include a T-shaped base material and/or other features related to base material(s) 124.

Where gate material 170 is included in bounding structure 160, adjacent portions of semiconductor layer 106 may define a “source region” or “drain region” (also known as “S/D” region) having a particular conductivity type, e.g., p-type doping. These portions of semiconductor layer 106 may be located adjacent channel region 162, which may be an undoped or more lightly doped region of semiconductor material as compared to semiconductor layer 106. In this configuration, semiconductor layer 106 may be only lightly doped or undoped. In some cases, semiconductor layer 106 may define part of a FET transistor structure in addition to those for BJT structure 150, i.e., by portions of semiconductor layer 106 acting as a diffusion region (i.e., a shared E/C and S/D region).

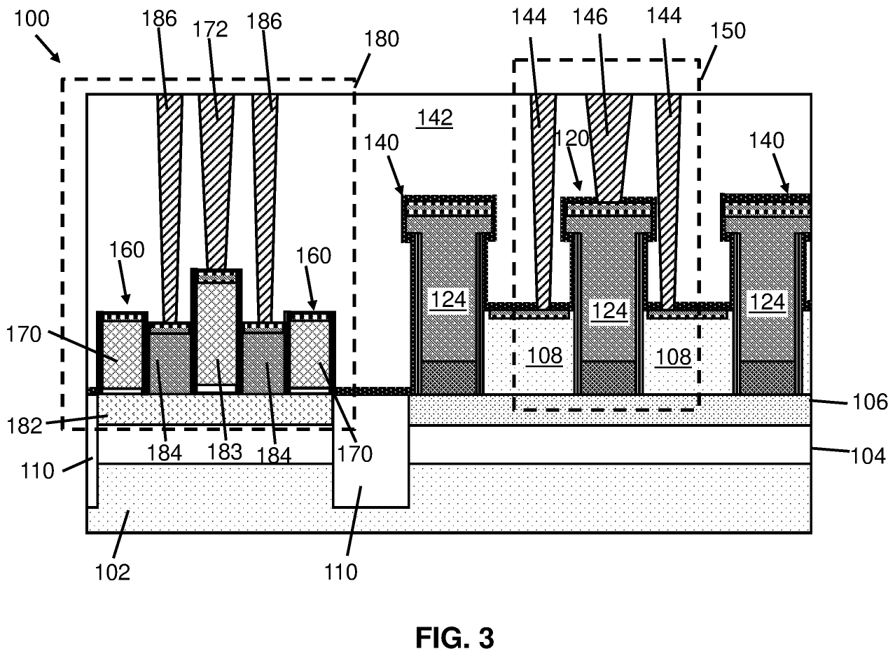

As shown in FIG. 3, bounding structure 140 with TI layer 110 may help to isolate BJT structure 150 from an adjacent FET structure 180 that is also on substrate 102. In this example, BJT structure 150 may be horizontally between two bounding structures 140. One bounding structure 140 on semiconductor layer 106 is also horizontally adjacent TI layer 110. In FET structure 180, a channel layer 182 may be on insulator layer 104 and may extend horizontally between two TI layers 110. Thus, one TI layer 110 horizontally separates channel layer 182 from semiconductor layer 106.

FET structure 180 may include an operative gate 183 on channel layer 182, in which operative gate is coupled to gate contact 172. A set of S/D regions 184 may be on channel layer 182 on opposite horizontal sides of operative gate 183. A set of S/D contacts 186 within ILD 142 may couple overlaying wires, vias, etc., to S/D regions 184. By applying a voltage to operative gate 183, a conductive pathway through channel layer 182 between S/D regions 184 can be created or inhibited. Optionally, FET structure 180 itself may include bounding structures 160 (e.g., including gate material 170 therein) adjacent S/D regions 184 such that each bounding structure 160 is between one S/D region 184 and TI layer 110. Bounding structures 140, 160 may allow active components of each transistor structure 150, 180 to be formed in closer proximity than would otherwise be possible, e.g., than if only TI layer(s) 110 were included on substrate 102 for horizontally separating different types of transistors. In the illustrated example, bounding structures 140, 160 for each transistor structure 150, 180 are free of conductive contacts thereon (i.e., they may serve no electrical biasing function), but this is not necessarily true in all implementations.

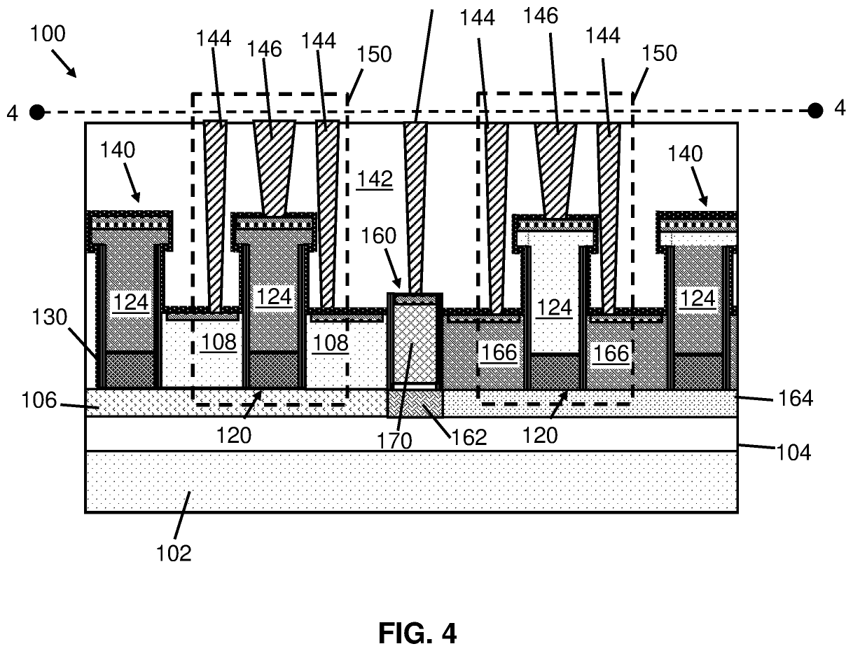

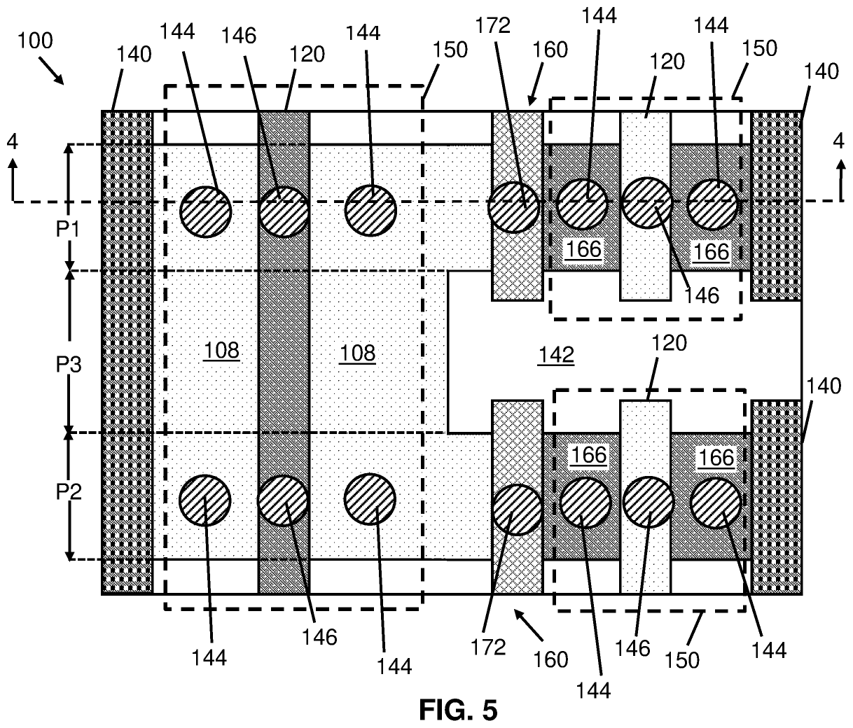

Referring now to FIGS. 4 and 5, embodiments of bounding structure 160 may allow selective intercoupling of multiple BJT structures 150 that are located on one substrate 102. FIG. 4 depicts a cross-sectional view of two BJT structure 150 along view line 4-4, and FIG. 5 depicts a plan view of BJT structure 150 to illustrate how more than two BJT structures 150 may be interconnected through bounding structures 160. According to an example, two horizontally adjacent BJT structures 150 may have the same polarities. For instance, E/C layers 108 of one BJT structure 150 may be doped p-type and additional E/C layers 166 of an adjacent BJT structure 150 may also be doped p-type. Base structures 120 within each BJT structure 150 may have the opposite conductivity type from that of the adjacent layers 108, 166. In further embodiments, two horizontally adjacent BJT structures 150 may have opposite polarities (and thus are illustrated with different types of cross-hatching). Bounding structure 160 may include gate material 170 with gate contact 172 and may be over channel region 162 as discussed herein. Bounding structure 160 is also located horizontally between the two BJT structures 150 over substrate 102 (FIG. 4 only). In this configuration, each E/C layers 108, 166 adjacent bounding structure 160 simultaneously functions as an E/C terminal for its respective BJT structure 150 and as a S/D terminal for bounding structure 160. Thus, applying a voltage to gate material 170 of bounding structure 160 selectively prohibits or inhibits current flow between E/C layers 108, 166.

Referring specifically to FIG. 5, BJT structures 150 may have a stem and leaf arrangement for selective coupling of one BJT structure 150 to one or more adjacent BJT structures 150. For example, one BJT structure 150 on the left-hand side of FIG. 5 is adjacent two different BJT structures 150 on opposite lengthwise ends. A first portion P1 of BJT structure 150 may be adjacent one adjacent BJT structure 150, a second portion P2 of BJT structure 150 may be adjacent another adjacent BJT structure 150, and an intermediate portion P3 of the left-hand BJT structure 150 may be adjacent ILD layer 142. The length of each BJT structure 150 can vary such that more than two BJT structures 150 are selectively coupled to another BJT structure 150 through bounding structure(s) 160 therebetween. During operation, one or more of bounding structures 160 can act as tie-down gates, and thus may be electrically biased to couple or decouple adjacent BJT structures 150. In this manner, bounding structures 160 can simultaneously provide electrical separation between adjacent BJT structures 150 and enable programmable logic functions by selective biasing of gate material 170 within bounding structures 160 that are between BJT structures 150. It is understood that more complex coupling arrangements are comprehended without departing from the scope of the present teachings.

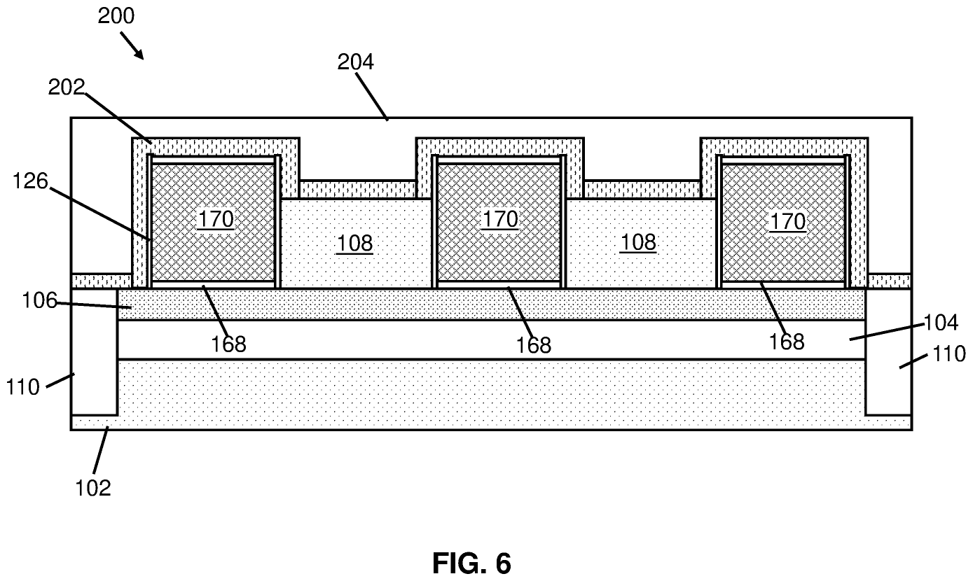

Turning to FIG. 6, embodiments of the disclosure also provide various methods to form structure 100 (FIGS. 1-5). Methods of the disclosure may include forming or otherwise providing an initial structure 200 including, e.g., substrate 102, insulator layer 104 on substrate 102, and semiconductor layer 106 on insulator layer 104. TI layer(s) 110 may be on substrate 102 and adjacent layers 104, 106, e.g., for horizontal separation of these layers from other active semiconductor materials. Initial structure 200 also may include E/C layers 108 on selected portions of semiconductor layer 106 and, initially, gate material(s) 170 on other portions of semiconductor layer 106. Gate material(s) 170 may include placeholder gate materials (e.g., polysilicon gates) or conductive gate structures (e.g., doped semiconductor material(s) and/or conductive metals) Gate material(s) 170 may include spacers 126, initially in the form of a spacer material that covers the upper surface(s) and sidewalls of each gate material(s) 170. The forming of initial structure 200 may include forming a first masking material 202 (e.g., by conformal deposition) over the upper surfaces of E/C layers 108 and gate material(s) 170, covering any portions of spacer(s) 126 that are on gate material(s) 170. First masking material 202 may include a nitride-base liner, oxide-based liner, and/or any other currently known or later developed masking materials. First masking material 202, in subsequent processing, may be operable to protect portions of E/C layer(s) 108 from being removed as selected gate material(s) 170 are removed and replaced. Initial structure 200 also may include a second masking material 204 (e.g., a nitride-based or oxide-based liner that may be similar to, or different from first masking material 202). Second masking material 204, however formed, may be planarized (e.g., by chemical mechanical planarization (CMP)) such that it has a planar upper surface located above first masking material 202 and any materials thereunder.

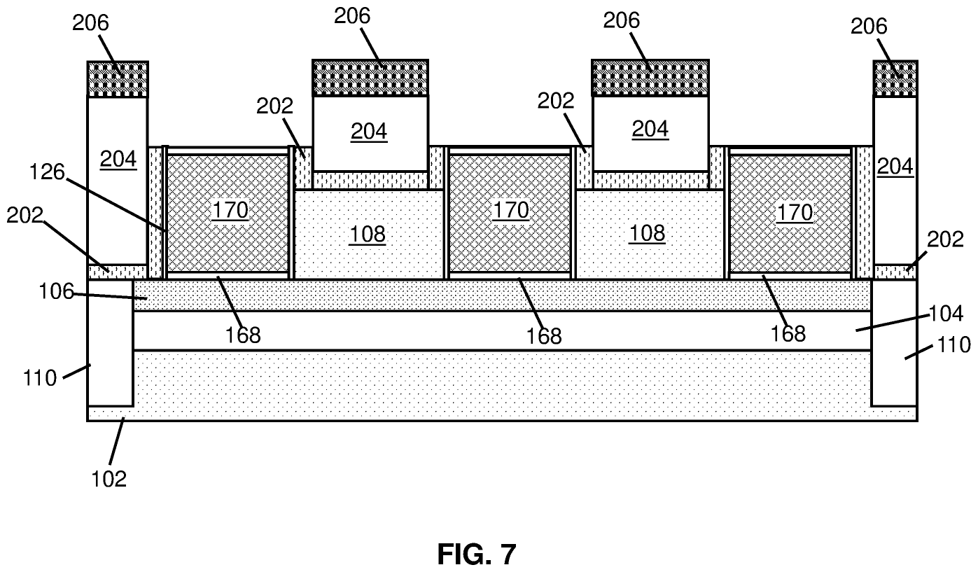

FIG. 7 depicts further processing to protect E/C layers 108 from removal during subsequent processing of gate material(s) 170. Embodiments of the disclosure may include forming an E/C mask 206 on portions of second masking material 204 that are not located over gate material(s) 170. E/C mask 206 may have a composition that is similar to or different from other masking material(s) 202, 204 discussed herein. With E/C mask 206 in place, portions of masking material(s) 202, 204 located over gate material(s) 170 may be removed (e.g., by directional etch) while masking material(s) 202, 204 covered by E/C mask 206 may remain intact. This process may expose upper surfaces of gate material(s) 170.

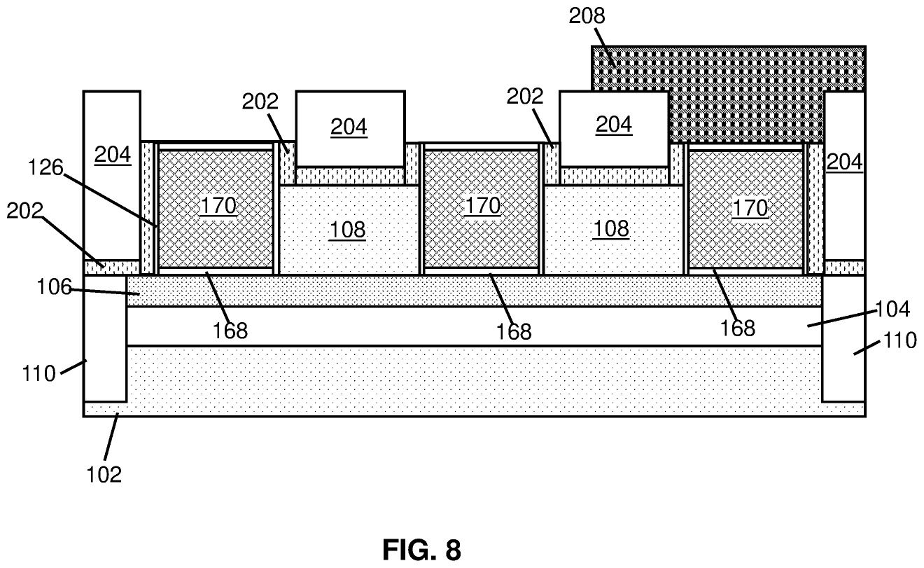

Referring briefly to FIG. 8, methods of the disclosure optionally may include forming an additional E/C mask 208 over gate material(s) 170 that will not be replaced with base material(s) 124, e.g., in base structure(s) 120 (FIGS. 1-5) and/or similarly composed bounding structures 140 (FIGS. 1-5). In some cases, E/C mask 206 (FIG. 7) itself may be shaped to include a region located over gate material(s) 170 that are not targeted for removal. In any case, E/C mask 206 and/or additional E/C mask 208 may be used to target certain gate material(s) 170 for removal and replacement while leaving other gate material(s) 170 intact over semiconductor layer 106.

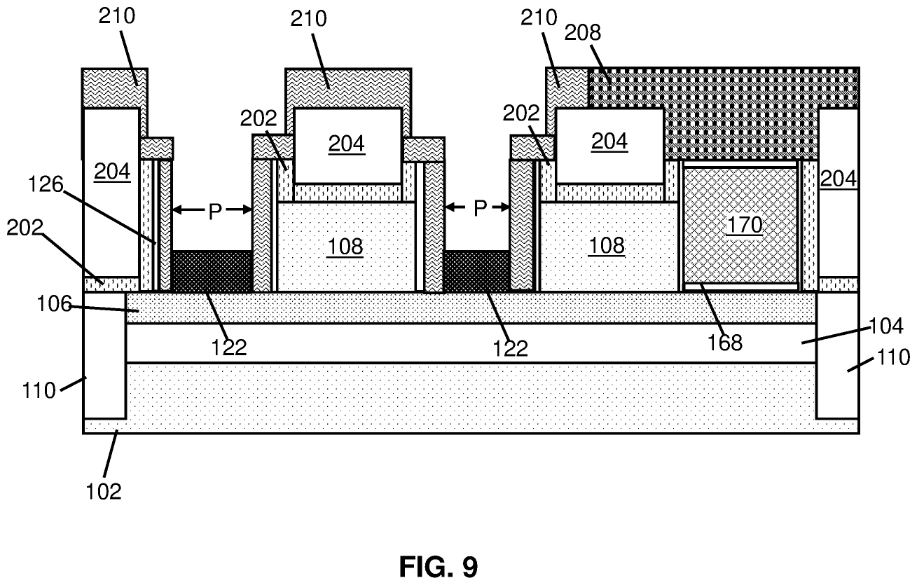

FIG. 9 depicts the removing of gate material 170 from semiconductor layer 106 in two locations, along with any previously formed gate dielectric layers 168 in these locations. These materials may be removed, e.g., by directional etching that is blocked elsewhere with additional E/C mask(s) 208. Where gate material 170 is removed, further processing may include forming insulative liner(s) 122 on exposed upper surfaces of semiconductor layer 106, and forming an inner spacer 210, e.g., as a single layer on exposed portions of previously formed spacer(s) 126, second masking material(s) 204, etc. Notwithstanding the forming of insulative liner(s) 122 and inner spacer(s) 210, the removing of gate material 170 may define a set of openings P above semiconductor layer 106.

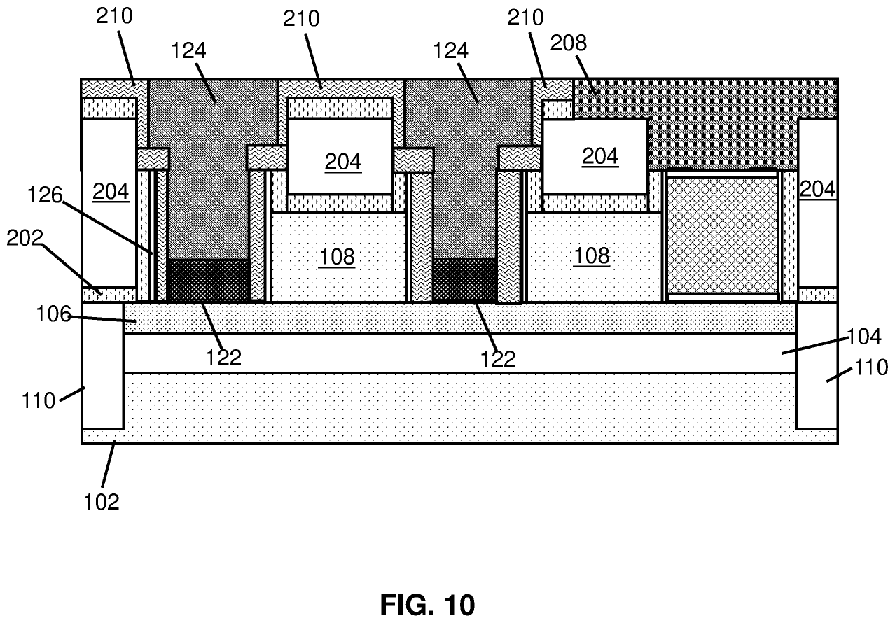

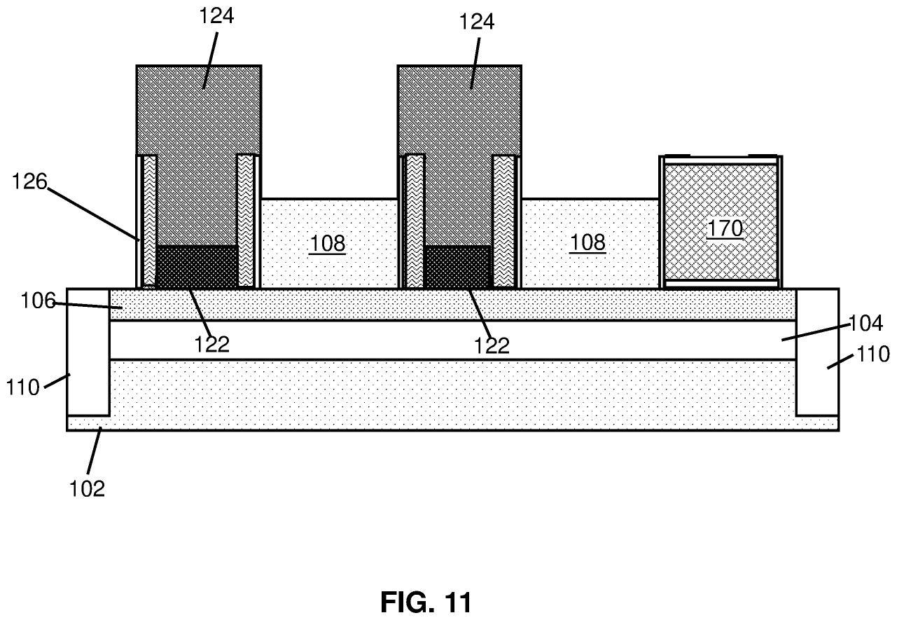

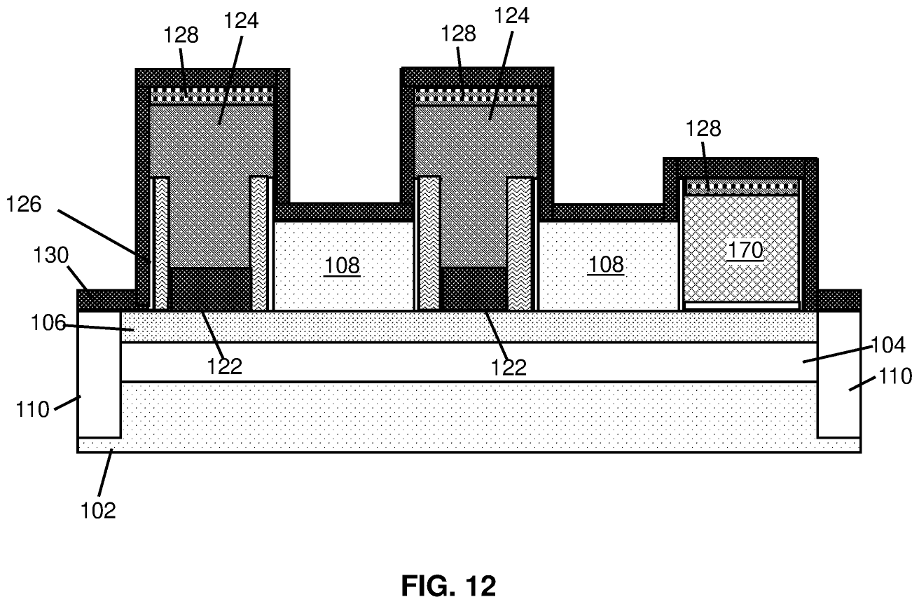

Turning to FIG. 10, further processing includes forming base material(s) 124 within opening(s) P, e.g., by epitaxial growth and doping of semiconductor materials discussed herein regarding base material(s) 124 within base structure 120 (FIGS. 1-5) or bounding structure 140 (FIGS. 1-5). Base material(s) 124 may be formed by growing such materials within opening(s) P and planarizing the material such that the upper surface(s) of base material(s) 124 are substantially coplanar with adjacent inner spacer 210 material and any additional E/C mask(s) 208. The forming of base material(s) 124 in this manner may produce substantially T-shaped regions of base material appropriate for use in base structure 120 and/or bounding structure 140.

In further processing, second masking material 204 can be removed by etching (e.g., isotropic or anisotropic selective etch), enabling silicidation and deposition of insulative coating 130. Downward etching and/or material removal techniques can expose E/C layer(s) 108, and also may expose upper surfaces of semiconductor layer 106 and/or TI layer(s) 110 that are not otherwise below E/C layer(s) 108, base material(s) 124, or gate material(s) 170.

Where desired, further processing may include forming silicide layers 128 on base material(s) 124 and gate material(s) 170, e.g., by depositing a conductive metal, annealing the metal such that portions of the metal migrate into the underlying semiconductor material, and removing any excess metal. Still further processing may include forming insulative coating 130 on any exposed surfaces of the resulting structure, e.g., to physically and electrically isolate base material(s) 124 and gate material(s) 170 from adjacent structures. Insulative coating 130 may be formed by conformal depositing of insulative coating(s) 130 to a desired thickness. Further manufacturing may continue substantially in accordance with conventional middle of line (MOL) and BEOL processing techniques, e.g., forming of ILD layer 142 and any contacts therein, to provide any desired embodiment of structure 100 (FIG. 1-5). Some portions of base material 124 (i.e., those located adjacent or between E/C layers 108) may define portions of a base structure 120 (FIGS. 1-5) in a bipolar transistor structure (150), whereas other portions of base material 124 and/or gate material 170 may define bounding structures 140, 160 (FIGS. 2-5).

Embodiments of the disclosure may provide several technical advantages, examples of which are discussed herein. For example, embodiments of the disclosure provide various types of bounding structures 140, 160 capable of strengthening electrical isolation between adjacent devices in MOL portions of structure 100. The forming of base material 124 with a T-shape geometry, where implemented, may reduce base and gate resistance within active portions of the device structure and related base width adjustments as compared to conventional transistor structures. These benefits may be enhanced by the presence of adjacent active semiconductor materials in bounding structures 140, 160, e.g., by enabling electrical biasing through bounding structures 140, 160. In the case of bounding structures 160, embodiments of the disclosure optionally provide a processing mechanism operable to form tie down gates within a relatively small surface area. Thus, embodiments of the disclosure may permit a circuit operator or designer to actively reconfigure logic or other device functions to suit varying needs.

The method and structure as described above is used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher-level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a center processor.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. “Optional” or “optionally” means that the subsequently described event or circumstance may or may not occur, and that the description includes instances where the event occurs and instances where it does not.

Approximating language, as used herein throughout the specification and claims, may be applied to modify any quantitative representation that could permissibly vary without resulting in a change in the basic function to which it is related. Accordingly, a value modified by a term or terms, such as “about,” “approximately,” and “substantially,” are not to be limited to the precise value specified. In at least some instances, the approximating language may correspond to the precision of an instrument for measuring the value. Here and throughout the specification and claims, range limitations may be combined and/or interchanged, such ranges are identified and include all the sub-ranges contained therein unless context or language indicates otherwise. “Approximately” as applied to a particular value of a range applies to both values, and unless otherwise dependent on the precision of the instrument measuring the value, may indicate+/−10% of the stated value(s).

The corresponding structures, materials, acts, and equivalents of all means or step plus function elements in the claims below are intended to include any structure, material, or act for performing the function in combination with other claimed elements as specifically claimed. The description of the present disclosure has been presented for purposes of illustration and description but is not intended to be exhaustive or limited to the disclosure in the form disclosed. Many modifications and variations will be apparent to those of ordinary skill in the art without departing from the scope and spirit of the disclosure. The embodiment was chosen and described in order to best explain the principles of the disclosure and the practical application, and to enable others of ordinary skill in the art to understand the disclosure for various embodiments with various modifications as are suited to the particular use contemplated.

What is claimed is:

1. A structure comprising:
a first emitter/collector (E/C) layer over a substrate;
a base structure over the substrate and adjacent to a first horizontal end of the first E/C layer;
a bounding structure over the substrate and adjacent a second horizontal end of the first E/C layer, wherein the bounding structure includes a base material; and
a spacer between the first E/C layer and the bounding structure.

2. The structure of claim 1, wherein the bounding structure is horizontally between the first E/C layer and a trench isolation (TI) layer.

3. The structure of claim 2, wherein the TI layer is horizontally between the bounding structure and a metal oxide semiconductor field effect transistor (MOSFET) structure.

4. The structure of claim 1, wherein the base structure includes a substantially T-shaped base material having a base contact thereon.

5. The structure of claim 1, wherein the bounding structure is free of conductive contacts thereon.

6. The structure of claim 1, wherein the bounding structure is on a semiconductor material having a same conductivity type as the E/C layer.

7. The structure of claim 1, further comprising:
a second emitter/collector (E/C) layer on the substrate, and having a first horizontal end adjacent the base structure such that the base structure is horizontally between the first E/C layer and the second E/C layer; and
an additional bounding structure over the substrate and adjacent a second horizontal end of the second E/C layer, wherein the additional bounding structure includes a gate conductor having a same doping type as, and a different composition from, the base material.

8. A structure comprising:
a first emitter/collector (E/C) layer over a substrate;
a base structure over the substrate and adjacent a first horizontal end of the first E/C layer, wherein the base structure includes a base material;
a bounding structure over the substrate and adjacent the first horizontal end of the first E/C layer, wherein the bounding structure includes a gate conductor having a different composition from the base material; and
a spacer between the first E/C layer and the bounding structure.

9. The structure of claim 8, wherein the E/C layer is within a first bipolar transistor and has a first conductivity type.

10. The structure of claim 9, wherein the bounding structure is horizontally between the first bipolar transistor and a second bipolar transistor, the second bipolar transistor having an additional E/C layer of the first conductivity type.

11. The structure of claim 9, wherein the bounding structure is on a semiconductor material having a different conductivity type from the E/C layer.

12. The structure of claim 11, further comprising:
a base contact on the base structure;
an E/C contact on the first E/C layer; and
a gate contact on the bounding structure, wherein a voltage bias of the gate contact controls conductivity through the semiconductor material.

13. The structure of claim 8, further comprising:
a second emitter/collector (E/C) layer over the substrate and having a first horizontal end adjacent the base structure such that the base structure is horizontally between the first E/C layer and the second E/C layer; and
an additional bounding structure over the substrate and adjacent a second horizontal end of the second E/C layer, wherein the additional bounding structure includes a base material free of conductive contacts thereon.

14. The structure of claim 13, wherein the additional bounding structure is horizontally between the second E/C layer and a trench isolation (TI) layer.

15. The structure of claim 14, wherein the TI layer is horizontally between the additional bounding structure and a metal oxide semiconductor field effect transistor (MOSFET) structure.

16. A method comprising:
providing a substrate; and
forming a bipolar junction transistor including at least:
a first emitter/collector (E/C) layer on the substrate;
a base structure on the semiconductor layer and adjacent a first horizontal end of the first E/C layer;
a bounding structure over the semiconductor layer and adjacent a second horizontal end of the first E/C layer, wherein the bounding structure includes a base material; and
a spacer between the first E/C layer and the bounding structure.

17. The method of claim 16, further comprising forming a trench isolation layer in the semiconductor layer, wherein the bounding structure and the first E/C layer are formed on the semiconductor layer so that the bounding structure is horizontally between the first E/C layer and the TI layer.

18. The method of claim 17, further comprising forming a field effect transistor (FET) structure adjacent the TI layer, wherein the TI layer is horizontally between the bounding structure and the FET structure.

19. The method of claim 16, wherein the bounding structure is formed on a semiconductor material having a same conductivity type as the E/C layer.

20. The method of claim 16, further comprising:
forming a second emitter/collector (E/C) layer over the substrate and having a first horizontal end adjacent the base structure such that the base structure is horizontally between the first E/C layer and the second E/C layer; and
forming an additional bounding structure over the substrate and adjacent a second horizontal end of the second E/C layer, wherein the additional bounding structure includes a gate conductor having a different composition from the base material.
